(19) United States
(12) Patent Application Publication
(10) Pub. No.: US 2010/0068882 A1
(43) Pub. Date: Mar. 18, 2010

(54) Semiconductor Device and Method for Manufacturing the Same

(76) Inventor: Ki Jun Yun, Suwon-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/559,108

(22) Filed: Sep. 14, 2009

(30) Foreign Application Priority Data
Sep. 16, 2008 (KR) 10-2008-0090717

(51) Int. Cl. H01L 21/3205

(52) U.S. Cl. 438/674; 257/E21.295

(57) ABSTRACT

The present method for manufacturing a semiconductor device comprises the steps of forming an aluminum wiring layer on a substrate; sequentially forming a hard mask, a polysilicon layer, and a bottom anti-reflective coating over the aluminum wiring layer; etching the polysilicon layer using a photoresist pattern formed over the bottom anti-reflective coating as mask; etching the hard mask to a predetermined thickness; and etching the hard mask to expose the aluminum wiring layer. The method for manufacturing a semiconductor device according to the present invention may prevent byproducts and polymer residue from when patterning the hard mask. As a result, the presently disclosed methods may avoid the need for a conventional cleaning process prior to etching the aluminum wiring layer to form aluminum lines.

### CROSS REFERENCE TO RELATED APPLICATION

This application claims the benefit of the Patent Korean Application No. 10-2008-0090717, filed on 16 Sep. 2008, which is hereby incorporated by reference as if fully set forth herein.

### BACKGROUND OF THE DISCLOSURE

1. Field of the Disclosure

The present invention relates to a semiconductor device, more particularly, to a semiconductor device and a method for manufacturing the device.

2. Discussion of the Related Art

In general, an etching mask is used to form a desired pattern. As the pitch of a metal wiring gets smaller (e.g., 120 nm or less), the thickness of a photoresist may be limited. To solve this limitation, a double mask structure using a thin layered oxide mask can be used.

FIG. 1a is a sectional view illustrating a conventional method for manufacturing semiconductor device.

In reference to FIG. 1a, according to a conventional back end process for forming metal lines, a first titanium nitride/titanium (TiN/Ti) thin film 12 is deposited on a substrate and an aluminum layer 14 for forming metal lines is deposited on the first TiN/Ti thin film 12. Subsequently, a second TiN/Ti thin film 16 is deposited on the aluminum layer 14 and the stack is patterned such that an aluminum wiring layer 20 is formed, including the first titanium nitride/titanium (TiN/Ti) thin film 12, the aluminum layer 14, and the second TiN/Ti thin film 16. The first and second titanium nitride/titanium (TiN/Ti) thin films 12 and 16 act as diffusion barrier layers for aluminum metal lines that are subsequently formed from the aluminum metal wiring layer 20.

An oxide mask 22, polysilicon layer 24, and a bottom anti-reflective coating layer 26 are sequentially formed over the second titanium nitride/titanium (TiN/Ti) thin film 16.

A photoresist layer is formed on the bottom anti-reflective coating layer 26 and a photoresist pattern 28 is formed by exposing and developing the photoresist layer using a pattern mask (not shown).

In reference to FIG. 1b, the bottom anti-reflective coating layer 26 and polysilicon layer 24 are etched using the photoresist pattern 28 as a mask. After etching the bottom anti-reflective coating (BARC) 26 and the polysilicon layer 24 using the photoresist pattern 28 as a mask, the oxide mask 22 is then etched (e.g., by a plasma etching process). During the etching process, polymer materials may be generated due reactions between the plasma, the photoresist, and possibly other materials in the layer(s) being etched. Thus, an undesired byproduct may be generated during the step of etching the oxide mask 22.

As shown in FIG. 1c, a polymer residue may be generated from the reaction of the plasma with the photoresist, and the residue may adhere to the exposed surfaces of TiN/Ti thin film 16 and the other layers (e.g., the BARC 26, the polysilicon layer 24, and the oxide layer 22) during the etching of the oxide mask 22. Subsequently, the second TiN/Ti thin film 16, the aluminum layer 14, and the first TiN/Ti thin film 12 are etched using the BARC 26, the polysilicon layer 24, and the oxide layer 22 to form aluminum metal line 14.

As shown in FIG. 1d, an exposed surface of the resulting aluminum metal line 14 is rough. This is due to the presence of the polymer residue generated in the oxide layer etching process during a process for patterning the second TiN/Ti thin film 16, the aluminum layer 14, and the first TiN/Ti thin film 12.

Various reactive materials are produced during the etching of the oxide hard mask 22 and polymer residue is generated as a result. The polymer remains on exposed surfaces (e.g., a top or side) of each metal line, which may increase surface resistance, and reduce reliability and device yield. Consequently, the polymer should be removed.

### SUMMARY OF THE DISCLOSURE

Accordingly, the present invention is directed to one or more methods for manufacturing a semiconductor device.

An object of the present invention is to provideone or more methods for manufacturing a semiconductor device that reduces or avoids byproduct deposition on a metal line when etching a hard mask.

Additional advantages, objects, and features of the disclosure will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims, as well as the appended drawings.

To achieve these objects and other advantages in accordance with the purpose of the invention, as embodied and broadly described herein, a method for manufacturing a semiconductor device may include: forming a diffusion barrier on a substrate; sequentially forming a hard mask layer, a polysilicon layer and a bottom anti-reflective coating on the diffusion barrier; etching the polysilicon layer using a photoresist pattern on the bottom anti-reflective coating as mask; partially etching portions of the hard mask corresponding to the photoresist pattern to a predetermined depth; and etching the hard mask a second time to expose the diffusion barrier.

The method(s) for manufacturing a semiconductor device according to the present invention may prevent the generation of byproduct when etching a hard mask (e.g., for etching a metal line having a pitch of 120 nm or less), without the requirement of a subsequent cleaning process. Thus, the presently disclosed methods simplify and reduce the costs of a semiconductor manufacturing process.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure.

In the drawings:

FIGS. 1a to 1d are cross-sectional views illustrating processes of a conventional method for manufacturing a semiconductor device;

FIGS. 2a to 2e are cross-sectional views illustrating processes for making exemplary structures in a method for manufacturing a semiconductor device according to one or more embodiments of the present invention;

FIG. 3a is an inline image of an exemplary semiconductor device after an oxide hard mask has been etched according to embodiments of the present invention;

FIG. 3b is an inline image of a semiconductor device after aluminum metal lines have been etched using an exemplary oxide hard mask according to embodiments of the present invention; and

FIG. 3c is a scanning electron microscope (SEM) photograph of cross-sections of exemplary metal lines formed according to embodiments of the present invention.

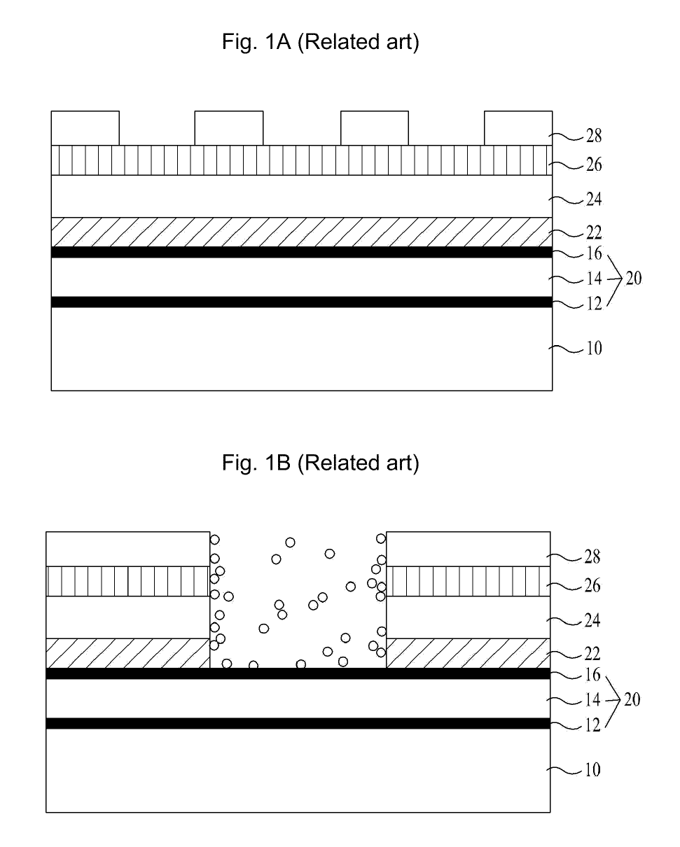

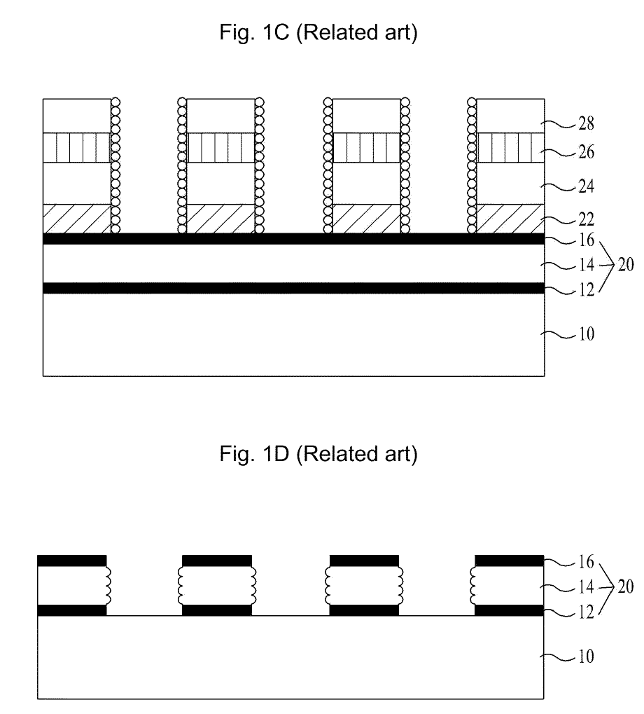

### DESCRIPTION OF SPECIFIC EMBODIMENTS

Reference will now be made in detail to the specific embodiments of the present invention, examples of which are illustrated in the accompanying drawings. Wherever possible, the same reference numbers will be used throughout the drawings to refer to the same or like parts.

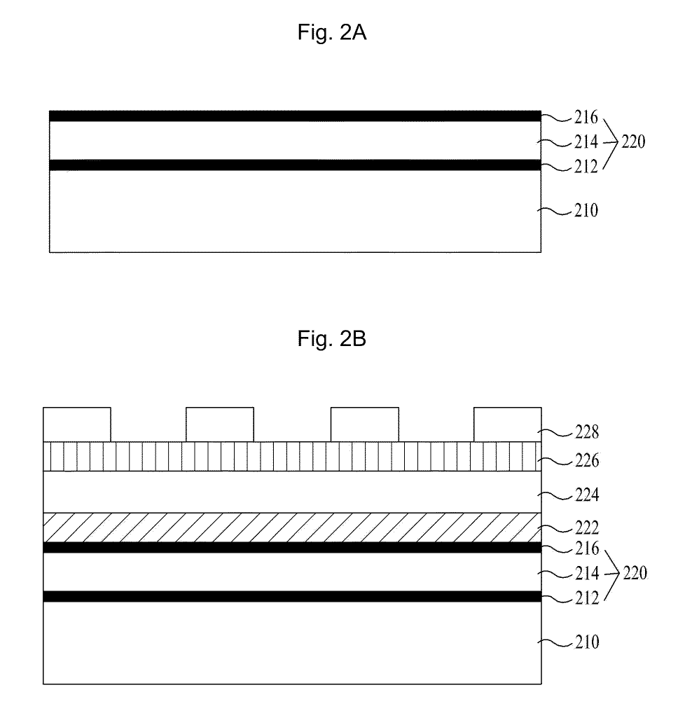

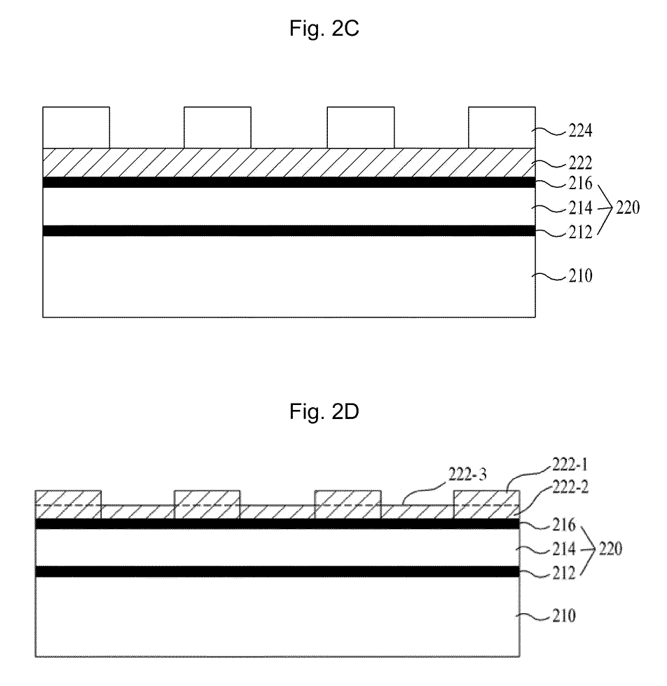

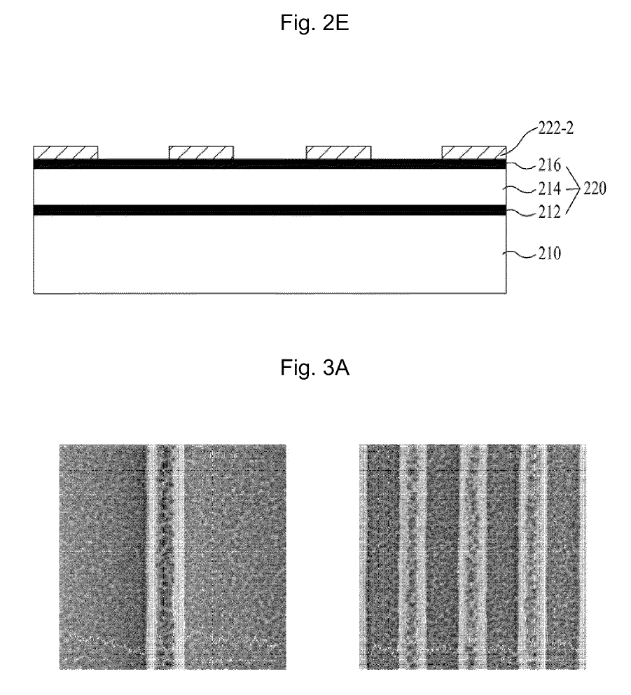

FIGS. 2a to 2e are cross-sectional views illustrating exemplary structures made during a method for manufacturing a semiconductor device according to exemplary embodiments of the present invention.

As shown in FIG. 2a, a back end process method for manufacturing a semiconductor device according to exemplary embodiments of the present invention includes depositing a first TiN/Ti thin film 212 on a substrate 200. An aluminum (Al) layer 214 can then be deposited on or over the first TiN/Ti thin film 212. A second TiN/Ti thin film 216 may then be deposited on or over the aluminum layer 214. The first and second TiN/Ti thin films form diffusion barriers for the aluminum layer 214. Generally, each TiN/Ti film may comprise a layer of TiN on a layer of Ti. The Ti layer may be deposited by sputtering from a TiN target or a Ti target in an atmosphere consisting essentially of one or more inert gases (e.g., He and/or Ar), and the TiN layer may be deposited by sputtering from a TiN target or a Ti target in an atmosphere containing a nitrogen source, such as N₂ and/or NH₃, or by chemical vapor deposition (CVD) from an organotitanium precursor (e.g., a compound of the formula Ti(NR₂)₄, where R is a C₁-C₄ alkyl group, such as methyl, ethyl, isopropyl or t-butyl) in an atmosphere containing a nitrogen source as described herein. Together, the first TiN/Ti thin film 212, the aluminum layer 214, and the second TiN/Ti thin film 216 form an aluminum wiring layer 220 that will be subsequently etched to form aluminum metal lines.

Alternatively, the layers of the aluminum wiring layer 220 (the TiN/Ti thin film 212, the thin Al layer 214, and the secondary deposition of the Tin/Ti thin film 216) may be formed through repeated depositions of monolayers of material. The deposition process may be repeated thousands of times for each layer.

The process of forming the aluminum wiring layer 220 will be described in detail as follows.

The first and second TiN/Ti thin films 212 and 216 are deposited under the same conditions in a deposition chamber (e.g., an atomic layer deposition chamber). An organic or inorganic material source gas may be used (e.g., an organometallic precursor such as tetrakis(dimethylamino)titanium (TMAT), or an inorganic precursor such as TiClₓ, where x=1-4 [e.g., 3 or 4, preferably 4]) and the source gas is supplied into the chamber for a period of about 0.05˜10 seconds.

Purge gas may be supplied into the chamber for about 0.5˜10 seconds after the supply of the source gas, to purge remaining source gas and any (gas-phase) byproduct(s). An inert gas (e.g., Ar, He, Kr, and/or Xe) or H₂ may be used as a purge gas.

The TiN/Ti thin films 212 and 216 may be deposited at a temperature of about 200˜700° C. (e.g., about 350˜550° C., or any range of values therein) and a process pressure of about 0.1˜100 torr (e.g., about 10˜50 torr, or any range of values therein).

Next, NH₃ may be supplied into the chamber as a reactive gas for about 0.5˜10 seconds to react with the deposited source material (e.g., Ti metal formed from TiClₓ) in order to form the TiN/Ti thin films 212 and 216. After supplying the reactive gas, any remaining reactive gas and byproduct may be purged using a purge gas (as described above), supplied for about 0.5˜10 seconds.

The source gas supply, reactive gas supply, and purge processes may compose a single cycle (e.g., source gas supply-purge-reactive gas supply-purge), and such a cycle may be repeated from hundreds to thousands of times to form TiN/Ti thin films (e.g., 212 and 216) having a desired thickness (e.g., about 100˜2000 nm, preferably 200˜800 nm, or any range of values).

Alternatively, the TiN/Ti thin films can be formed by depositing a Ti thin film by repeated cycles of ALD (e.g., a film having a thickness of about 50˜1000 nm), and then forming a TiN layer thereover by repeated cycles of supplying a Ti source gas (as described above) and supplying NH₃ gas into the chamber, with intervening purge processes. For example, the Ti source gas and the NH₃ gas can be supplied into the chamber at a temperature of about 200˜700° C. for about 0.05˜10 seconds.

In a further alternative, an organic Ti source material and a nitrogen source such as N₂ or hydrazine (N₂H₄) may be alternatingly introduced into the chamber during the deposition process of the TiN films during the cycle to form the TiN layers in thin films 212 and 216. Then, a multi-layered aluminum layer 214 is formed on the TiN/Ti thin film 212. The aluminum layer 214 may be formed by atomic layer deposition as well. The aluminum layer 214 may be deposited to a thickness of about 1000˜5000 nm (e.g., about 2000˜3000 nm, or any range of values therein). Alternatively, the aluminum layer 214 can be formed by a chemical vapor deposition technique (e.g., LPCVD, HPCVD, or PECVD) or physical vapor deposition (e.g., sputtering or evaporation).

That is, after the TiN/Ti thin film 212 is deposited, an aluminum source gas (e.g., trimethylaluminum [TMA, Al₂(CH₃)₆]) can be supplied into the chamber. The Al layer 214 can be formed in a similar process to the ALD deposition cycles described above: multiple, repeated deposition and purge steps can be sequentially performed multiple times (e.g., 100 to 100,000 times) to deposit the thin aluminum layer 214. Here, an inert gas (e.g., Ar, He, Kr, and/or Xe) or H₂ may be used as the purge gas.

As shown in FIG. 2b, an oxide hard mask layer 222, a polysilicon layer 224, and a bottom anti-reflective coating 226 for forming a mask pattern are sequentially deposited on the aluminum wiring layer 220.

A photoresist layer can then be formed on the bottom anti-reflective coating 226, and a photoresist pattern 228 can be formed by exposing and developing the photoresist layer using a pattern mask (not shown). The photoresist pattern 228 provides an etching mask that will be translated to the oxide hard mask layer 222 through multiple etching steps. The photoresist pattern 228 may be used as a mask for etching bottom anti-reflective coating 226 and the polysilicon layer 224. The photoresist pattern 228 and the etched bottom anti-reflective coating 226 can be removed and the etched polysilicon layer 224 can then be used as a mask for etching the oxide hard mask layer 222.

It is preferable that the hard mask layer 222 is formed by Plasma Enhanced Chemical Vapor Deposition (PE-CVD) using a silicon source gas such as SiH₄ in an oxygen-containing atmosphere at a temperature of about 300˜800° C. (e.g., 300-450° C. for low temperature deposition, or any other range of values therein). Alternatively, the oxide hard mask can be deposited by Low Pressure CVD (LPCVD) of tetraethyl orthosilicate (TEOS) in an oxygen-containing atmosphere at a temperature of about 500˜900° C. (e.g., 650˜800° C., or any other range of values therein). In a further alternative, the oxide hard mask can be formed by conventionally depositing a silicon layer (e.g., by CVD) and subsequent thermal oxidation of the silicon layer at a temperature of about 600˜1400° C. (e.g., about 800˜1000° C., or any other range of values therein). The thickness of the oxide hard mask 222 may be about 150 Å-400 Å.

A KrF light source may be used in patterning the photoresist pattern 228. The photoresist pattern 228 is patterned to have a pitch of 120 nm or less (e.g., about 20˜100 nm, 90 nm or less, or any other range of values therein). Alternatively, the photoresist pattern 228 can be exposed using a UV lamp, or other conventional means.

As shown in FIG. 2c, the polysilicon layer 224 is etched (e.g., by plasma etching) using the photoresist pattern 228 as a mask. Subsequently, both the photoresist pattern 228 and the bottom anti-reflective coating 226 are removed by conventional means (e.g., by blanket anisotropic etch and/or a photoresist stripping step).

As shown in FIGS. 2d and 2e, the oxide hard mask layer 222 may be etched in two separate hard mask etching steps. The first etching step divides the oxide hard mask layer into a top hard mask layer 222-1 and a bottom hard mask layer 222-2. The bottom hard mask includes an etched portion 222-3 exposed by the polysilicon layer 224 during the first hard mask etching step. Thus, the oxide hard mask layer 222 may be etched twice, which may include two different methods, resulting in the top hard mask layer 222-1 and the bottom hard mask layer 222-2.

In reference to FIG. 2d, for example, the top hard mask 222-1 is etched by plasma etching using the etched polysilicon layer 224 as a mask.

The selectivity ratio of a selected etching gas for etching polysilicon to oxide may be at least about 10:1 in the plasma etching step. The selected etching gas may comprise a combination of Cl₂ and HBr, Cl₂ and O₂, or HBr and O₂.

During the first plasma etching step, the exposed regions of the hard mask layer 222 may be etched to a depth of about 80˜95% of its thickness. Thus, the etched portion 222-3 may have a thickness of about 5˜20% of the original thickness of the hard mask layer 222.

The polysilicon layer 224 can be subsequently removed by plasma etching (e.g., using a Br- or Cl-containing gas, such as Cl₂, HBr, Br₂, or HCl) to expose the top hard mask layer 222-1.

In reference to FIG. 2e, a second hard mask etching step may be performed, which completely removes etched portion 222-3 of the bottom hard mask layer 222-2 to expose portions of an upper surface of the aluminum wiring layer 220. The top hard mask layer 222-1 is also removed during the second hard mask etching step, leaving only unetched portions of bottom hard mask layer 222-2 shown in FIG. 2e. The second hard mask etching step may include reactive ion etching (RIE).

In one embodiment, the second hard mask etching step can be performed using the same etching gas that is used in the first hard mask etching step. Since the photoresist pattern 228 has been removed (along with the other layers that were over the oxide hard mask 222), formation of polymer residue can be avoided in the second hard mask etching step to expose the second TiN/Ti thin film 216. Thus, the present method reduces or avoids forming aluminum metal lines 214 with a rough sidewall surface.

Alternatively, the gas used in the second hard mask etching step may comprise or consist essentially of CF₄, Ar and/or O₂. Ar gas has a sputter-etching effect, and O₂ gas increases the oxide hard mask etch rate.

Specifically, the RIE etch of the etched portions 222-3 of the bottom oxide hard mask 222-2, and the top oxide hard mask 222-1 may be performed the following etching gas recipe.

POWER: about 2 MHz, about 0˜200 W

PRESSURE: about 60˜85 mT

CF₄: about 50˜100 sccm

Ar: about 250˜350 sccm

O₂: about 0˜5 sccm

Subsequently, the aluminum wiring layer 220 (including the first TiN/Ti thin film 212, the aluminum layer 214, and the second TiN/Ti thin film 216) is etched using the oxide hard mask 222 as an etch mask. For example, the aluminum wiring layer 220 may be etched by RIE.

As mentioned above, the hard mask 222 is double-etched to divide it into the top hard mask layer 222-1 and the bottom hard mask 222-2. The bottom hard mask layer 222-2 adjacent to the second TiN/Ti thin film 216 is etched in a separate step from the etching method of the hard mask layer 222-1. As a result, byproduct generated by the reaction between various materials during a conventional oxide mask etch may be prevented.

Furthermore, during the following etching of the aluminum layer 214, roughness in the sidewall surfaces of the aluminum lines 214 may be reduced enough to reduce or substantially prevent formation of metal bridges between adjacent aluminum lines 214.

Still further, the presently disclosed methods may provide adequate margin for a metal line forming process for a 90 nm and lower generation semiconductor devices. Additionally, the presently disclosed methods may reduce or avoid the need for a conventional cleaning process. Thus, the presently disclosed methods simplify and reduce the costs of a semiconductor manufacturing process.

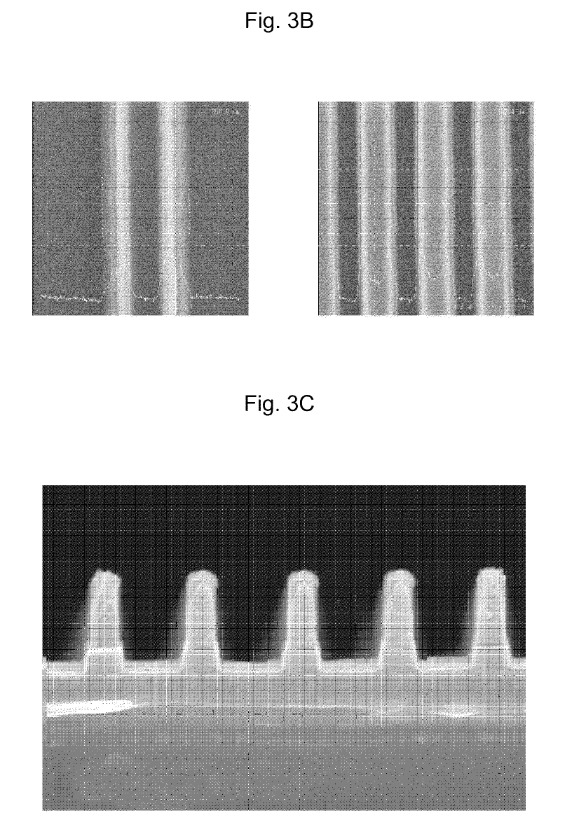

FIGS. 3a to 3c are inline images of exemplary structures formed after the double etching steps to form the oxide hard mask according to the present invention. FIG. 3B shows an inline image of aluminum lines after etching the aluminum wiring layer, and FIG. 3B shows a SEM photograph of a cross-section of the aluminum lines. The inline images show that there is little effect from any polymer residue that may be present in the etched areas, and that the widths of the etched recesses are substantially uniform. The SEM photograph shows that the aluminum lines have a substantially smooth exposed surface, resulting from the hard mask method disclosed herein.

In reference to FIGS. 3a to 3c, there may be little to no byproduct remaining after the hard mask etching according to the present invention and the roughness of the aluminum lines following an aluminum etching step may be prevented enough to reduce surface resistance efficiently.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a semiconductor device comprising steps of:
forming a diffusion barrier on a substrate;
sequentially forming a hard mask layer, a polysilicon layer and a bottom anti-reflective coating over the diffusion barrier;
etching the polysilicon layer using a photoresist pattern on the bottom anti-reflective coating as a mask;
etching regions of the hard mask layer corresponding to the photoresist pattern by a predetermined thickness; and
etching a remaining thickness of the hard mask layer to expose the aluminum wiring layer.

2. The method of claim 1, wherein the predetermined thickness is about 80-95% of a total thickness of the hard mask layer.

3. The method of claim 1, wherein etching a remaining thickness of the hard mask layer comprises using CF₄, Ar, and O₂ as etching gases.

4. The method of claim 3, wherein the CF₄, Ar and O₂ etching gases are supplied at a total pressure in a range of 60˜85 mTorr.

5. The method of claim 3, wherein etching a remaining thickness of the hard mask layer is performed at about 2 MHz, and about 0˜200 W.

6. The method of claim 3, wherein the flow rate of the CF₄ is about 50˜100 sccm.

7. The method of claim 3, wherein the flow rate of the Ar is about 250˜350 sccm.

8. The method of claim 3, wherein the flow rate of the O₂ is about 0˜2 sccm.

9. The method of claim 1, wherein forming the aluminum wiring layer comprises sequentially depositing a first TiN/Ti thin film, an aluminum layer, and a second Tin/Ti thin film.

10. The method of claim 9, wherein depositing the first TiN/Ti thin film comprises depositing a Ti thin film on the substrate by atomic layer deposition, and treating the Ti thin film with a NH₃ plasma.

11. The method of claim 10, wherein depositing the aluminum layer comprises depositing an aluminum film over the first TiN/Ti thin film by atomic layer deposition.

12. The method of claim 11, wherein depositing the second TiN/Ti thin film comprises depositing a Ti thin film over the aluminum layer by atomic layer deposition, and treating the Ti thin film with NH₃ gas.

13. The method of claim 12, wherein forming the first and second TiN/Ti thin films comprises repeated monolayer deposition steps until the TiN/Ti thin films have a desired thickness.

14. The method of claim 13, wherein a source gas for forming the first and second TiN/Ti thin films comprises an organic or inorganic titanium source gas.

15. The method of claim 14, wherein forming the first and second TiN/Ti thin films comprises supplying the titanium source gas into a deposition chamber for about 0.05˜10 seconds.

16. The method of claim 15, wherein forming the first and second TiN/Ti thin films comprises supplying a purge gas comprising an inert or H₂ gas into the deposition chamber for about 0.5˜10 seconds after the source gas is supplied into the deposition chamber.

17. The method of claim 16, wherein the NH₃ gas is supplied into the deposition chamber for about 0.5˜10 seconds to react with the Ti thin films to form the TiN/Ti thin films.

18. The method of claim 1, wherein forming the hard mask comprises forming a silicon oxide layer by plasma enhanced chemical vapor deposition (PE-CVD) using SiH₄ as a source gas in an oxygen atmosphere.

19. The method of claim 1, wherein the hard mask layer has a thickness of 150 Å to 400 Å.

20. The method of claim 1, further comprising forming the photoresist pattern on the bottom anti-reflective coating.
